(19) United States
(12) Patent Application Publication
(10) Pub. No.: US 2025/0389782 A1
(43) Pub. Date: Dec. 25, 2025

(54) INTERNAL SHORT CIRCUIT DETECTION

(71) Applicant: GM GLOBAL TECHNOLOGY OPERATIONS LLC, Detroit, MI (US)

(72) Inventors: James C Gibbs, Brighton, MI (US); Andrew C Baughman, Northville, MI (US)

(73) Assignee: GM GLOBAL TECHNOLOGY OPERATIONS LLC, Detroit, MI (US)

(21) Appl. No.: 18/749,376

(22) Filed: Jun. 20, 2024

(51) Int. Cl. G01R 31/392; B60L 3/00; B60L 58/26; G01R 31/367; G01R 31/3842; G01R 31/389; G01R 31/396

(52) U.S. Cl. CPC G01R 31/392; B60L 3/0046; B60L 58/26; G01R 31/367; G01R 31/389; G01R 31/396; B60L 2240/547; B60L 2240/549; G01R 31/3842

(57) ABSTRACT

A method includes operating a device having a rechargeable energy storage system (RESS) including parallel groups of cells having overcurrent protection elements, by passing a current through the cells based on instructions provided by a processor; obtaining sensor data via sensors; determining, via the processor, whether a cell group has a decreasing resistance rate of change; when the cell group has a decreasing resistance rate of change, determining, via the processor, whether the cell group has a sufficient voltage deviation indicative of an internal short circuit condition; when the cell group does not, determining, via the processor, whether the cell group has a voltage rate of change unrelated to the current; and when the cell group has a voltage rate of change unrelated to the current, concluding, via the processor, that an internal short circuit exists and modifying operation of the device to prevent damage to the RESS.

### INTRODUCTION

The technical field generally relates to rechargeable energy storage systems (“RESS”) and more particularly relates to methods and systems for detecting internal short circuits in cells within rechargeable energy storage systems.

Rechargeable energy storage systems, including lithium-ion and related batteries, are increasingly being used in a variety of fields as a way to more efficiently generate, store, and distribute electrical power. In automotive applications, rechargeable energy storage systems are being used as a way to supplement, in the case of hybrid electric vehicles (HEVs), or supplant, in the case of purely electric vehicles (EVs), i.e., battery electric vehicles (BEVs), conventional internal combustion engines. The ability to passively store energy from stationary and portable sources, as well as from recaptured kinetic energy provided by the vehicle and its components, makes batteries ideal to serve as part of a propulsion system for cars, trucks, buses, motorcycles and related vehicular platforms. In the present context, a cell is a single electrochemical unit, whereas a battery is made up of one or more cells joined in series, parallel or both, depending on desired output voltage and capacity.

Temperature is one of the most significant factors impacting both the performance and life of a battery. Environmental temperatures (such as those encountered during protracted periods of inactivity in cold or hot environments, or due to extended periods of operation and concomitant heat generation on hot days) or abuse conditions (such as the rapid charge/discharge, or internal/external shorts caused by the physical deformation, penetration, or manufacturing defects of the cells) can negatively impact the ability of the battery to operate correctly, and in severe cases can destroy the battery entirely. Side effects of prolonged exposure to high temperature may include premature aging and accelerated capacity fade, both of which are undesirable.

Excess heat can be provided by an internal short circuit in a battery cell. An onset temperature is that temperature at which an exothermic reaction occurs. The heat required to maintain such an exothermic reaction is known as the heat of reaction, while a heat source that exceeds the onset temperature and maintains the heat of reaction is a thermal event. Such thermal events, if left uncontrolled, could potentially lead to a more accelerated heat generation condition, referred to herein as thermal runaway, a condition where (once initiated) the cooling mechanism is incapable of returning one or more of the battery components to a safe operating temperature. In the present context, a thermal runaway is a function of the self-heating rate of the exothermic reaction and the temperature, and the time of the reaction is a function of the rate of degradation and the mass of active components taking part in such reaction. Of particular concern is the possibility for excess heating of, and concomitant damage to, a battery cell, group, pack or related member being used as a source of propulsive power.

Accordingly, it is desirable to provide methods and systems for diagnosing internal short circuits in a cell group as early as possible to provide mitigation before excess heat causes thermal runaway. Furthermore, other desirable features and characteristics of the present disclosure will become apparent from the subsequent detailed description and the appended claims, taken in conjunction with the accompanying drawings and the foregoing introduction.

### SUMMARY

In an embodiment, a method includes operating a device having a rechargeable energy storage system (RESS) including cells arranged in parallel in cell groups, wherein each cell is provided with an overcurrent protection element, by passing a current through the cells based on instructions provided by a processor; obtaining sensor data via one or more sensors of the device; determining, via the processor, whether a cell group has a decreasing resistance rate of change; when the cell group has a decreasing resistance rate of change, determining, via the processor, whether the cell group has a sufficient voltage deviation indicative of an internal short circuit condition; when the cell group does not have a sufficient voltage deviation indicative of an internal short circuit condition, determining, via the processor, whether the cell group has a voltage rate of change that is unrelated to the current; and when the cell group has a voltage rate of change that is unrelated to the current, concluding, via the processor, that an internal short circuit exists and modifying operation of the device to prevent damage to the RESS.

In certain embodiments, the method further includes concluding, via the processor, that an internal short circuit exists and modifying operation of the device to prevent damage to the RESS when the cell group has a sufficient voltage deviation indicative of an internal short circuit condition.

In certain embodiments of the method, modifying operation of the device to prevent damage to the RESS includes cooling the RESS and/or discharging the RESS.

In certain embodiments, the method further includes determining, via the processor, whether an overcurrent protection element in the cell group has opened when the cell group does not have a voltage rate of change that is unrelated to the current; and concluding, via the processor, that the overcurrent protection element opened due to fatigue when an overcurrent protection element in the cell group has opened.

In certain embodiments, the method further includes determining, via the processor, whether the cell group has an increasing resistance rate of change when the cell group does not have a decreasing resistance rate of change; determining, via the processor, whether an overcurrent protection element in the cell group has opened when the cell group has an increasing resistance rate of change; and concluding, via the processor, that the overcurrent protection element opened due to fatigue and modifying operation of the device when an overcurrent protection element in the cell group has opened.

In certain embodiments of the method, modifying operation of the device includes revising charging and discharging limits of the RESS to avoid damaging the cell group; and revising RESS output estimates based on a decreased storage capability of the cell group.

In certain embodiments of the method, the device is a battery electric vehicle (BEV).

In certain embodiments of the method, the device is a hybrid electric vehicle (HEV).

In another embodiment, method includes operating a device having a rechargeable energy storage system (RESS) including cells arranged in parallel in cell groups, wherein each cell is provided with an overcurrent protection element, by passing a current through the cells based on instructions provided by a processor; obtaining sensor data via one or more sensors of the device; performing, via the processor, an initial diagnosis of the sensor data to ascertain whether an internal short circuit condition exists, wherein the initial diagnosis does not ascertain that an internal short circuit condition exists; and performing, via the processor, a secondary diagnosis of the sensor data to ascertain whether an internal short circuit condition exists, wherein the secondary diagnosis considers sensor data behavior representative of an opened overcurrent protection element.

In certain embodiments of the method, performing the initial diagnosis includes determining whether a voltage of an affected cell group exhibited a voltage decrease with a greater magnitude than a threshold value representative of the internal short circuit condition.

In certain embodiments of the method, performing the secondary diagnosis includes determining whether the voltage of the affected cell group exhibited an initial voltage decrease representative of the internal short circuit condition before the voltage of the affected cell exhibited an increasing voltage indicative of the opened overcurrent protection element.

In certain embodiments of the method, performing the secondary diagnosis includes determining whether a voltage rate of change of the affected cell group is unrelated to the current.

In certain embodiments, the method further includes performing, via the processor, a tertiary diagnosis of the sensor data to ascertain whether an overcurrent protection element has opened when the secondary diagnosis ascertains that an internal short circuit condition does not exist

In certain embodiments of the method, performing the tertiary diagnosis includes monitoring a capacity of each cell group and determining that the capacity of the cell group of the affected cell has decreased; and/or monitoring a resistance of each cell group and determining that the resistance of the cell group of the affected cell has increased.

In certain embodiments, the method the method further includes modifying, via the processor, limits and calculations for controlling operation of the device to compensate for the RESS limited by an affected cell group with a diminished capacity when the tertiary diagnosis concludes that an overcurrent protection element has opened.

In another embodiment, a vehicle includes a rechargeable energy storage system (RESS) including cells arranged in parallel in cell groups, wherein each cell is provided with an overcurrent protection element; sensors configured to obtain sensor data regarding voltage, resistance, and/or capacity of each cell group; a processor that is coupled to the sensors and is configured to: instruct the RESS to pass a current through the cells to drive the vehicle; obtain the sensor data from the sensors; perform an initial diagnosis of the sensor data to ascertain whether an internal short circuit condition exists; and perform a secondary diagnosis of the sensor data to ascertain whether an internal short circuit condition exists, wherein the secondary diagnosis considers sensor data behavior representative of an opened overcurrent protection element.

In certain embodiments of the vehicle, the initial diagnosis includes determining whether a voltage of an affected cell group exhibited a voltage decrease with a greater magnitude than a threshold value representative of the internal short circuit condition.

In certain embodiments of the vehicle, the secondary diagnosis includes determining whether the voltage of the affected cell group exhibited an initial voltage decrease representative of the internal short circuit condition before the voltage of the affected cell exhibited an increasing voltage indicative of the opened overcurrent protection element.

In certain embodiments of the vehicle, the secondary diagnosis includes determining whether the voltage rate of change of the affected cell group is unrelated to the current.

In certain embodiments of the vehicle, the processor is configured to perform a tertiary diagnosis of the sensor data to ascertain whether an overcurrent protection element has opened; the tertiary diagnosis includes monitoring the capacity of each cell group and determining that the capacity of the cell group of the affected cell has decreased; and/or monitoring the resistance of each cell group and determining that the resistance of the cell group of the affected cell has increased; and the processor is configured to modify limits and calculations for controlling operation of the vehicle to compensate for the RESS limited by the affected cell group with a diminished capacity when the tertiary diagnosis concludes that an overcurrent protection element has opened.

### DESCRIPTION OF THE DRAWINGS

The present disclosure will hereinafter be described in conjunction with the following drawing figures, wherein like numerals denote like elements, and wherein:

FIG. 1 is a functional block diagram of a vehicle that includes an RESS and a control system for control thereof, among various other components, in accordance with exemplary implementations;

FIG. 2 is a schematic illustrated battery cells in cell groups in a portion of the RESS of FIG. 1;

FIG. 3 is a graph illustrating a general voltage response for a cell group after a circuit of a battery cell is opened in an application involving repeated discharging and charging of the RESS.

FIG. 4 is a graph illustrating a general voltage response for a cell group after a circuit of a battery cell is opened in an application involving constant charging of the RESS.

FIG. 5 is a flowchart illustrating a method for controlling operation of a RESS to determine whether an internal short circuit exists when an overcurrent protection element opens.

FIG. 6 is a graph illustrating a voltage change over time for a cell group with a cell having an internal short circuit and then having an overcurrent protection element open as compared to normally operating cell groups.

FIG. 7 is a flowchart illustrating a method for controlling operation of a RESS to determine whether an internal short circuit exists when an overcurrent protection element opens.

FIG. 8 is a flowchart illustrating a method for determining whether an overcurrent protection element in a RESS has opened based on cell group capacity.

FIG. 9 is a flowchart illustrating a method for determining whether an overcurrent protection element in a RESS has opened based on cell group resistance.

FIG. 10 is a graph illustrating a general resistance per increment response for a cell group after a circuit of a battery cell is opened.

### DETAILED DESCRIPTION

The following detailed description is merely exemplary in nature and is not intended to limit the disclosure or the application and uses thereof. Furthermore, there is no intention to be bound by any theory presented in the preceding introduction or summary or the following detailed description.

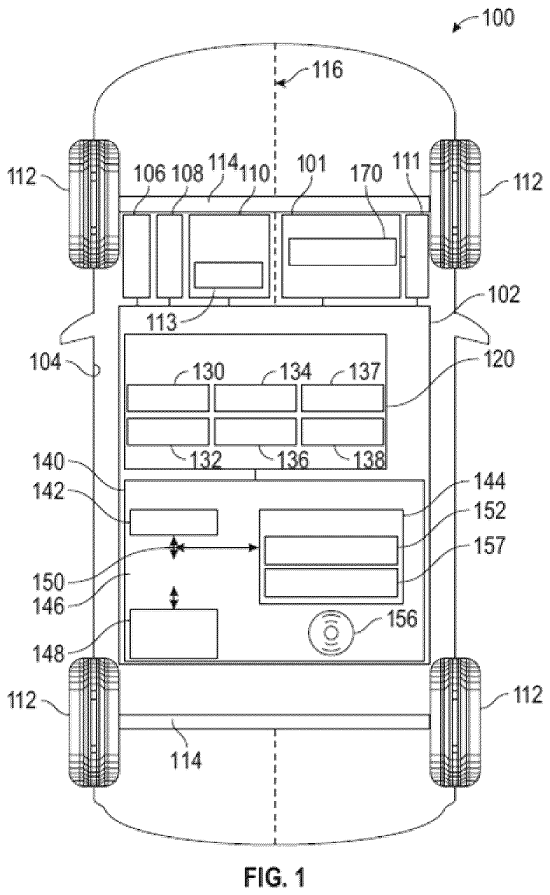

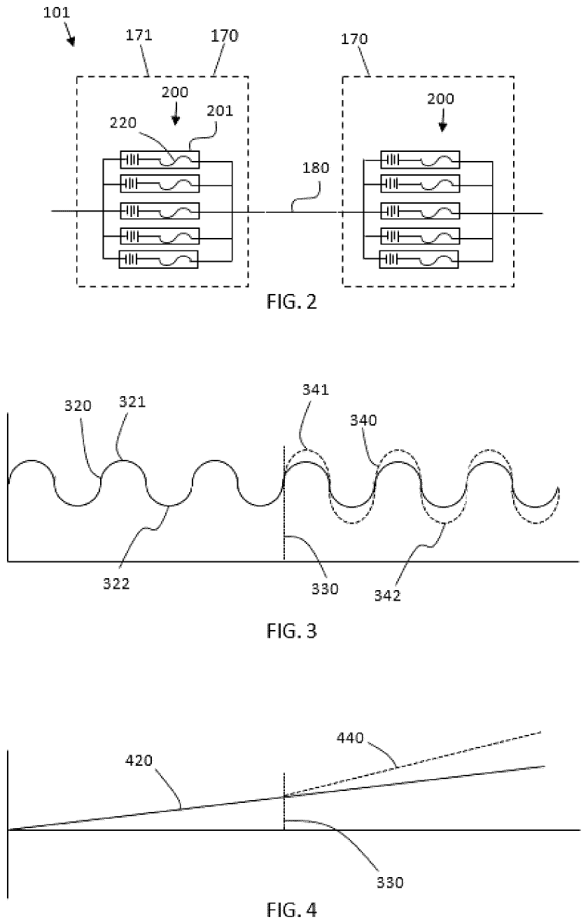

FIG. 1 illustrates a vehicle 100, according to an exemplary implementation. As described in greater detail further below, the vehicle 100 includes, among other components, a rechargeable energy storage system (“RESS”) 101 and a control system 102. In various implementations, the RESS 101 includes a plurality of cell groups 170, for example as depicted in FIG. 2 and described in greater detail further below in connection therewith. Also in various implementations, the control system 102 controls the RESS 101.

As depicted in FIG. 1, the RESS 101 and control system 102 are depicted as part of the vehicle 100 in accordance with exemplary implementations. In various implementations, the vehicle 100 comprises an automobile, such as any one of a number of different types of automobiles, such as, for example, a sedan, a wagon, a truck, sport utility vehicle (SUV), or the like. In certain implementations, the vehicle 100 may also comprise a motorcycle or other vehicle, such as aircraft, spacecraft, watercraft, and so on, and/or one or more other types of mobile platforms (e.g., a robot and/or another mobile platform). In yet other implementations, the RESS 101 and control system 102 may instead be part of and/or coupled to any number of other types of platforms and/or other systems, moving or non-moving, such as a building, infrastructure, secondary use, home power, non-automotive, and/or other platforms and/or other systems.

In the depicted implementation, the vehicle 100 includes a body 104 that is arranged on a chassis 116. The body 104 substantially encloses other components of the vehicle 100. The body 104 and the chassis 116 may jointly form a frame. The vehicle 100 also includes a plurality of wheels 112. The wheels 112 are each rotationally coupled to the chassis 116 near a respective corner of the body 104 to facilitate movement of the vehicle 100. In one implementation, the vehicle 100 includes four wheels 112, although this may vary in other implementations (for example for trucks, motorcycles, and certain other vehicles).

A drive system 110 is mounted on the chassis 116, and drives the wheels 112, for example via axles 114. In certain implementations, the drive system 110 comprises a propulsion system having an electric motor 113. In various implementations, the drive system 110, including the motor 113, receives high voltage from the RESS 101.

In various implementations, in addition to providing the high voltage to the motor 113, the RESS 101 also provides low voltage to one or more low voltage systems 111 of the vehicle 100. In various implementations, the low voltage systems 111 may include, by way of example, one or more climate control systems, radio systems, seat warming systems, and so on.

As depicted in FIG. 1, the vehicle also includes a braking system 106 and a steering system 108 in various implementations. In exemplary implementations, the braking system 106 controls braking of the vehicle 100 using braking components that are controlled via inputs provided by a driver (e.g., via a brake pedal) and/or automatically via a control system (such as the control system 102 and/or one or more other control systems). Also in exemplary implementations, the steering system 108 controls steering of the vehicle 100 via steering components that are controlled via inputs provided by a driver (e.g., via a steering wheel), and/or automatically via a control system (such as the control system 102 and/or one or more other control systems).

In the implementation depicted in FIG. 1, the control system 102 is coupled to the RESS 101, receives inputs therefrom, and controls functionality thereof. In addition, in certain implementations, the control system 102 is coupled to one or more of the braking system 106, steering system 108, drive system 110, and/or low voltage systems 111, and may also receive inputs from and/or control these additional systems in certain implementations.

Also as depicted in FIG. 1, in various implementations, the control system 102 includes a sensor array 120 and a control module 140 (or controller), as described in greater detail below.

In various implementations, the sensor array 120 includes various sensors that obtain sensor data of the vehicle 100 for use in controlling, among other functionality, the RESS 101. In the depicted implementation, the sensor array 120 includes one or more voltage sensors 130, current sensors 132, temperature sensors 134, state of charge sensors 136, brake sensors 137, and steering sensors 138.

In certain implementations, the voltage sensors 130 measure voltage of the RESS 101, including of the various cell groups 170 thereof. Also in certain implementations, the current sensors 132 measure electric current of the RESS 101, including of the cell groups 170 thereof. In various implementations, the temperature sensors 134 measure temperature of the RESS 101, including of the cell groups 170 thereof. Also in various implementations, the state of charge sensors 136 measure state of charge of the RESS 101, including of the cell groups 170 thereof. In addition, various implementations, the brake sensors 137 measure one or more parameters pertaining to the braking system 106 (e.g., braking inputs, braking force, or the like), whereas the steering sensors 138 measure one or more parameters pertaining to the steering system 108 (e.g., steering inputs, steering angle, or the like).

In various implementations, the control module 140 is coupled to the sensor array 120 and receives sensor data therefrom. In various implementations, the control module 140 is further coupled to the RESS 101. In addition, in certain implementations, the control module 140 may also be coupled to one or more other systems of the vehicle 100, such as the braking system 106, steering system 108, drive system 110, and/or low voltage systems, for example for receiving input thereof and/or for controlling thereof.

As depicted in FIG. 1, in various implementations, the control module 140 comprises a computer system, and includes a processor 142, a memory 144, an interface 146, a storage device 148, and a computer bus 150.

The processor 142 performs the computation and control functions of the control module 140, and may comprise any type of processor or multiple processors, single integrated circuits such as a microprocessor, or any suitable number of integrated circuit devices and/or circuit boards working in cooperation to accomplish the functions of a processing unit. During operation, the processor 142 executes one or more programs 152 contained within the memory 144 and, as such, controls the general operation of the control module 140 and the computer system of the control module 140, generally in executing the processes described herein.

The memory 144 can be any type of suitable memory, including various types of non-transitory computer readable storage medium. In certain examples, the memory 144 is located on and/or co-located on the same computer chip as the processor 142. In the depicted implementation, the memory 144 stores the above-referenced program 152 along with stored values 157 (e.g., look-up tables, thresholds, and/or other values with respect to control of the RESS 101).

The interface 146 allows communication to the computer system of the control module 140, for example from a system driver and/or another computer system, and can be implemented using any suitable method and apparatus. In one implementation, the interface 146 obtains the various data from the sensor array 120, among other possible data sources. The interface 146 can include one or more network interfaces to communicate with other systems or components. The interface 146 may also include one or more network interfaces to communicate with technicians, and/or one or more storage interfaces to connect to storage apparatuses, such as the storage device 148.

The storage device 148 can be any suitable type of storage apparatus, including various different types of direct access storage and/or other memory devices. In one exemplary implementation, the storage device 148 comprises a program product from which memory 144 can receive a program 152 that executes one or more implementations of one or more processes of the present disclosure, such as the steps of the method 500 of FIG. 5 and described further below in connection therewith. In another exemplary implementation, the program product may be directly stored in and/or otherwise accessed by the memory 144 and/or a disk (e.g., disk 156), such as that referenced below.

The bus 150 serves to transmit programs, data, status and other information or signals between the various components of the computer system of the control module 140. The bus 150 can be any suitable physical or logical means of connecting computer systems and components. This includes, but is not limited to, direct hard-wired connections, fiber optics, infrared and wireless bus technologies. During operation, the program 152 is stored in the memory 144 and executed by the processor 142.

It will be appreciated that while this exemplary implementation is described in the context of a fully functioning computer system, those skilled in the art will recognize that the mechanisms of the present disclosure are capable of being distributed as a program product with one or more types of non-transitory computer-readable signal bearing media used to store the program and the instructions thereof and carry out the distribution thereof, such as a non-transitory computer readable medium bearing the program and containing computer instructions stored therein for causing a computer processor (such as the processor 142) to perform and execute the program.

FIG. 2 is a functional diagram of a portion of the RESS 101 of FIG. 1, and that includes a plurality of cell groups 170, in accordance with exemplary implementations.

As depicted in FIG. 2, in various implementations, the RESS 101 includes a number of cell groups 170, such as the illustrated first cell group 170 and second cell group 170B, and so on, up to an “nth” cell group. In certain embodiments, the cell groups 170 are connected in series via bus bar 180. The cells group may be configured electrically in series as shown and/or in parallel. It will be appreciated that the number and configuration of cell groups 170 may vary in different implementations, and the subject matter described herein is not limited to any particular number, type or configuration of cell groups 170.

In certain embodiments, each cell group 170 may include one or more battery cells 200 or other energy storage elements that are configured electrically in parallel as shown to provide a desired DC voltage level and/or DC output current. While each cell group 170 is illustrated as including five battery cells 200, the number of battery cells 200 per cell group 170 may be any desired suitable number.

Further, as shown, each battery cell 200 is provided with an overcurrent protection element 220. For example, each battery cell 200 may be provided with an internal overcurrent protection element 220. Alternatively, each battery cell 200 may be provided with an external overcurrent protection element 220. In various embodiments, the RESS 101 may include overcurrent protection elements 220 in the form of internal fuses, external fuses, fuse links or fusible links, fuse busbars or other fuse cell connections. In certain embodiments, each battery cell 200 is provided with a dedicated overcurrent protection element 220.

With the structure of the cell groups 170 and battery cells 200 of FIG. 2, the opening of a circuit through a selected battery cell 201 by an overcurrent protection element 220 results in known changes electrical performance. For example, when a circuit of a single battery cell 201 in cell group 171 is opened by the overcurrent protection element 220, the capacity of the affected cell group 171 is reduced by 20% as compared to normally operating cells groups 170. Further, when a circuit of a single battery cell 201 in cell group 171 is opened by the overcurrent protection element 220, the resistance of the affected cell group 171 is increased by 25% as compared to normally operating cells groups 170.

FIG. 3 is a graph illustrating a general voltage response for an affected cell group 171 after a circuit of a selected battery cell 201 is opened by the overcurrent protection element 220. In FIG. 3, voltage is plotted on the Y-axis and time is plotted on the X-axis. In FIG. 3, the RESS 101 is repeatedly discharged and charged, such as during typical usage by a hybrid electric vehicle (HEV). As shown, the voltage 320 increases from low voltage troughs 322 to high voltage peaks 321 as the cell group 170 is charged, and decreases from high voltage peaks 321 to low voltage troughs 322 as the cell group 170 is discharged.

In FIG. 3, the overcurrent protection element 220 of a single battery cell 201 in the cell group 171 opens at time 330, reducing the cell group 171 to four operable battery cells 201. Afterwards, the voltage 340 is shown to fluctuate between higher voltage peaks 341 and lower voltage troughs 342 as compared to a cell group 170 with five operable battery cells 201.

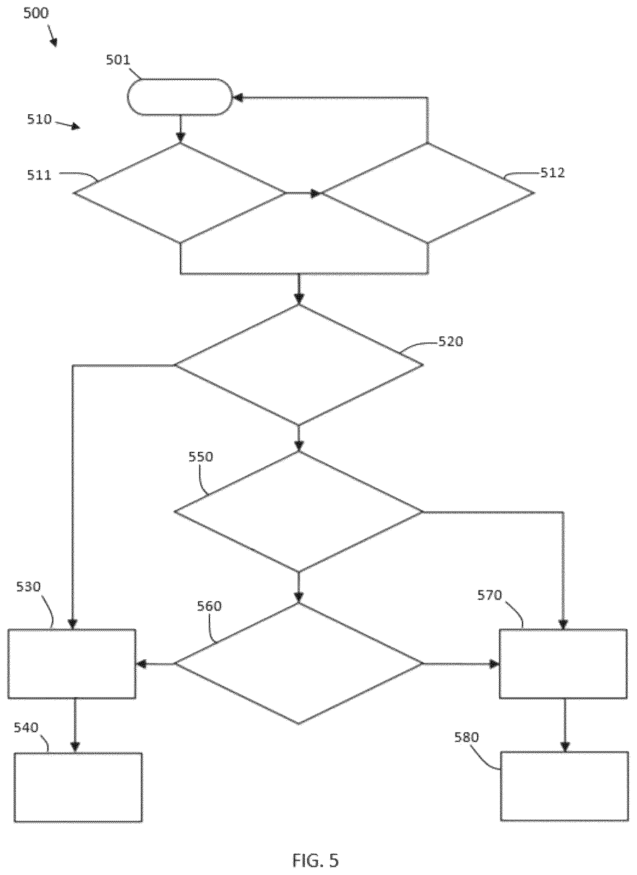

FIG. 4 is another graph illustrating a general voltage response for a cell group 171 after a circuit of a selected battery cell 201 is opened by the overcurrent protection element 220. In FIG. 4, voltage is plotted on the Y-axis and time is plotted on the X-axis. In FIG. 4, the RESS 101 is charged continuously, such as during typical usage by a battery electric vehicle (BEV). As shown, the voltage 420 increases at a constant rate as the cell group 171 is charged when the cell group 171 has five operable battery cells 200.

In FIG. 4, the overcurrent protection element 220 of a single battery cell 201 in the cell group 171 opens at time 330, reducing the cell group 171 to four operable battery cells 201. Afterwards, the voltage 440 is shown to increase at a faster rate as compared to a cell group 170 with five operable battery cells 201.

Cross-referencing FIGS. 2-4, it can be seen that when there is an internal short circuit in a selected battery cell 201, the current to the parallel cells 200 in the cell group 170 will be drawn to the shorted cell 201 and the voltage for the cell group 170 will drop. Then, the overcurrent protection element 220 opens the circuit to the short cell 201 in an attempt to prevent the internal short circuit from increasing temperature sufficient to start a thermal runaway event.

When the overcurrent protection element 220 opens, the current to the cell group 171, which is planned for use with five battery cells 200, is now directed to the four remaining operable battery cells 200. As a result, the RESS 101 may experience control problems. For example, because the remaining operable battery cells 200 are receiving more of the current load than planned for, the remaining operable battery cells 200 are more likely to fail, such as in a cascading failure. Also, when the circuit of a battery cell 201 opens, the affected cell group 171 may be the limiting factor in performance of the RESS 101. Thus, even if the remaining operable battery cells 200 in the affected cell group 170 do not fail, the affected cell group 171 will charge the fastest among the cell groups 170 in the RESS 101, as indicated by FIGS. 3 and 4, and will discharge the fastest among the cell groups 170 in the RESS 101, as indicated by FIGS. 3 and 4. Further, the battery cells 200 in the affected cell group 171 will reach the upper voltage limits and the lower voltage limits most often and most quickly, as compared to the other cell groups 170 in the RESS 101. Such behavior may cause the control system 102 to try to protect the affected cell group 171. As a result, the device may exhibit poor performance. For example, a vehicle with a RESS 101 with an affected cell group 171 may have poor drivability, may be provided with poor estimates for driving range or remaining charge, and/or may be provided with poor estimates for charging time.

Embodiments herein provide for protecting the RESS 101 from damage while improving RESS performance, such as after an overcurrent protection element 220 opens.

A method 500 for operating a RESS, such as RESS 101 is illustrated in FIG. 5. As shown, the method 500 may begin at start operation 501. Method 500 includes, at operation 510, diagnosing whether an overcurrent protection element has opened in a cell group in the RESS. Specifically, at query 511, method 500 determines whether a cell group (CG) capacity delta, i.e., change in capacity, exists. If a change in cell group capacity exists, then an overcurrent protection element has opened and the method may continue at query 520. If no change in cell group capacity exists, then operation 510 proceeds to query 512, which determines whether a cell group (CG) resistance delta, i.e., change in cell group resistance, exists. If a change in cell group resistance exists, then an overcurrent protection element has opened and the method may continue at query 520. If no change in cell group resistance exists, then the method 500 may re-start at operation 501.

At query 520, method 500 determines whether an internal short circuit (ISC) condition was diagnosed. For example, a drop in voltage from a cell group may be identified and used to diagnose that an internal short circuit condition exists. Thus, query 520 may determine whether the voltage decrease met the threshold.

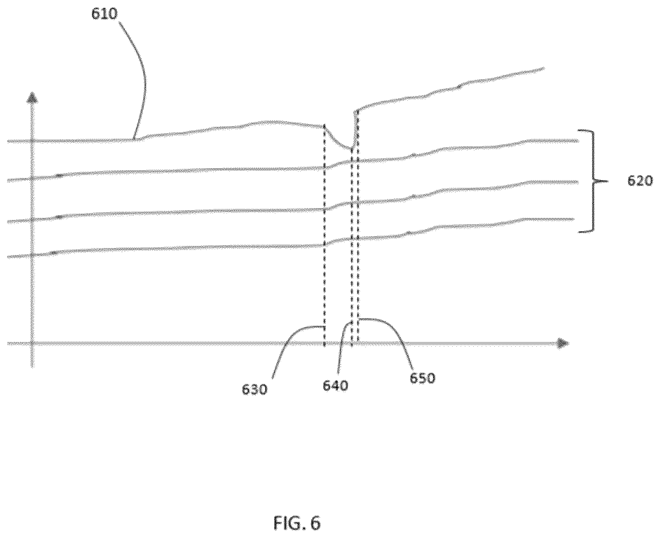

Referring to FIG. 6, a general voltage graph is illustrated, with voltage on the Y-axis and time on the x-axis. It is noted that the voltage for each cell group may be relatively the same, but are shown spaced apart on the y-axis for clarity. The graph illustrates a voltage 610 of a selected cell group and voltages 620 of other cell groups. In the selected cell group, a battery cell experiences an internal short circuit and then an overcurrent protection element opens to protect the cell group. Specifically, the internal short circuit occurs at time 630 and the overcurrent protection element opens at time 640. As shown, beginning at time 630, the voltage 610 drops. At the same time, the voltages 620 exhibit no decrease. Then, at time 640, the voltage 610 of the selected cell group increases quickly to return to the previous level and then exhibits a growing increase as compared to voltages 620. Such behavior is evidence of an initial internal short circuit, indicated by the voltage decrease from time 630 to time 640; and of the opening of an overcurrent protection element, indicated by the increasing voltage after time 640.

As shown in FIG. 6, all the voltages 620 of the other cell groups follow essentially the same contour. However, voltage 610 exhibits a dip of a predictable manner indicative of an internal short circuit. Specifically, the internal short circuit pulls down the voltage 610, and when the overcurrent protection element opens, the cell group voltage rebounds. In a cell group having an opened overcurrent protection element caused by fatigue or heavy usage, the dip from time 630 to time 640 will not be present. Rather, the cell group will exhibit an increasing voltage relative to the other voltages 620, such as after time 650.

Referring back to FIG. 5, if an internal short circuit (ISC) condition is diagnosed at query 520, method 500 may proceed at operation 530 and conclude that an internal short circuit has occurred. After concluding that an internal short circuit has occurred, method 500 continues at operation 540 with performing thermal runaway mitigation processes, such as to prevent increasing heat in the RESS. For example, operation 540 may include preventing charging of the RESS, discharging power from the RESS, cooling the RESS, issuing appropriate warnings to an operator of the RESS, or a combination thereof.

At query 520, if an internal short circuit (ISC) condition is not diagnosed at query 520, for example because no cell group exhibited a sufficient voltage drop, then method 500 may continue at query 550.

At query 550, method 500 determines whether internal short circuit (ISC) indications were present but not sufficient to be diagnosed at query 520. For example, an initial voltage drop may have occurred briefly before being stopped due to the opening of an overcurrent protection element. In certain embodiments, the method identifies certain behavior patterns as internal short circuit indications.

For example, the method may look for an erratic cell voltage, i.e., a cell voltage that is not trending like the rest of the cell voltages. In certain cases, the erratic cell voltage may drop down faster than other cell voltages, or rise faster than other cell voltages. In other words, the method monitors for unexpected departures or deviations from the behavior of other cells. In certain embodiments, a monitor may be dedicated to looking for an erratic cell voltage as a deviation from the behavior of other cells. Further, the method may look for a magnitude of the deviation of a cell voltage compared to other cell voltages. For example, a monitor may be dedicated to tracking the value of the deviation of the erratic cell voltage. The two monitors in combination may evaluate not only the absolute amount of bias monitored, but erratic movement of that bias within the absolute bias threshold.

If query 550 determines that internal short circuit (ISC) indications were present, then method 500 continues at query 560 with determining whether independent internal short circuit (ISC) indications exist. For example, query 560 may determine whether internal short circuit indications dissipate in a profile consistent with the opening of an overcurrent protection element. Generally, query 550 looks for non cell voltage related indications. For example, temperatures sensors may indicate that the local temperature near a specific cell has increased at a faster rate than temperatures monitored farther from the specific cell. By itself, such a temperature rise may not indicate an internal short circuit, but a temperature rise may be used to corroborate other internal short circuit indications.

If query 560 determines that independent internal short circuit (ISC) indications exist, then method 500 concludes that an internal short circuit exists at operation 530 and performs thermal runaway mitigation processes at operation 540.

If query 560 determines that internal short circuit (ISC) indications do not exist, the method 500 concludes at operation 570 that the overcurrent protection element opened due to fatigue or heavy usage, and not due to an internal short circuit. Method 500 then continues at operation 580 with controlling operation of the RESS to compensate for the loss of a cell group. For example, operation 580 may include modifying limits and calculations for controlling operation of the RESS.

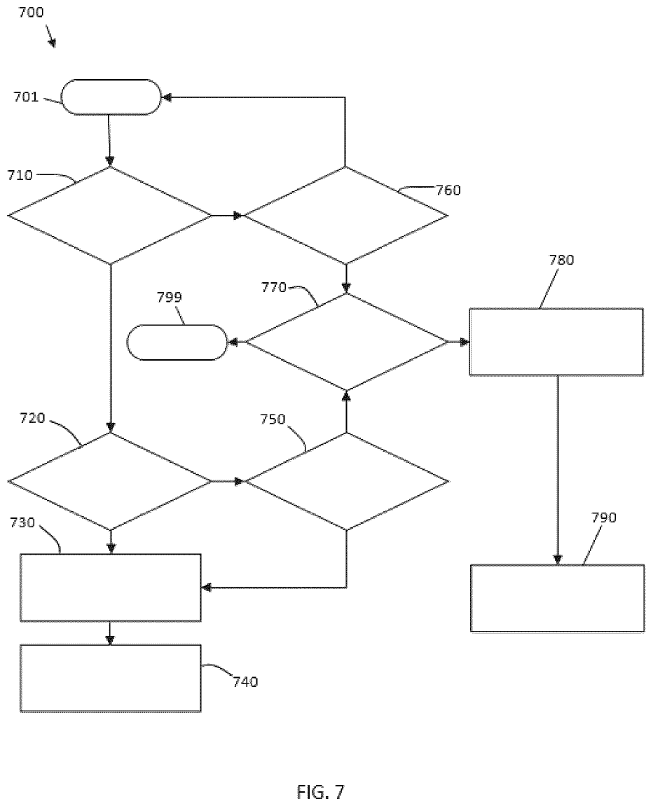

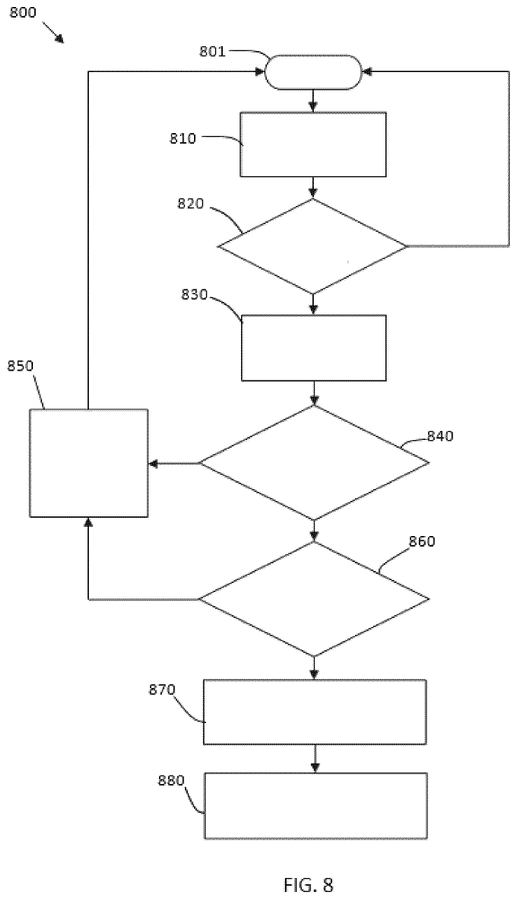

FIG. 7 is a flow chart illustrating a method for operating a RESS, such as RESS 101. As shown, the method 700 may begin at start operation 701. Method 700 includes, at query 710, determining whether a decreasing cell group (CG) resistance rate of change is detected for any cell group. If query 710 determines that a decreasing cell group (CG) resistance rate of change is detected, then method 700 continues at query 720.

Query 720 determines whether sufficient voltage deviation is detected for the affected cell group. For example, query 720 may determine whether a decrease in voltage of the affected cell group met a threshold indicative of an internal short circuit.

If query 720 determines that a sufficient voltage deviation is detected, then method 700 continues at operation 730 with concluding that an internal short circuit exists in the affected cell group. Then, method 700 continues at operation 740 with performing thermal runaway mitigation processes, such as to prevent increasing heat in the RESS. For example, operation 740 may include preventing charging of the RESS, discharging power from the RESS, cooling the RESS, issuing appropriate warnings to an operator of the RESS, or a combination thereof.

If query 720 determines that a sufficient voltage deviation is not detected, then method 700 continues at query 750. At query 750, method 700 determines whether the voltage rate of change of the affected cell group is unrelated to the current of the cell group.

If query 750 determines that the voltage rate of change of the affected cell group is unrelated to the current of the cell group, then method 700 concludes that an internal short circuit exists in the affected cell group. Then, method 700 continues at operation 740 with performing thermal runaway mitigation processes.

If query 750 determines that the voltage rate of change of the affected cell group is not unrelated to the current of the cell group, then method 700 proceeds to query 770. At query 770, method 700 determines whether fuse monitoring detecting is open, i.e., that a fuse has opened. In other words, if the voltage movement is unrelated to current changes, then an internal short circuit is diagnosed. If the voltage movement is not unrelated to current changes, i.e., the voltage readings are related to current, then a fuse has opened.

If query 770 determines that fuse monitoring detecting is open, then method 700 proceeds to operation 780. Operation 780 concludes that the overcurrent protection element opened due to fatigue or heavy usage, rather than due to an internal short circuit. Method 700 then continues at operation 790 with controlling operation of the RESS to compensate for the loss of a cell group. For example, operation 790 may include modifying limits and calculations for controlling operation of the RESS.

If query 770 determines that fuse monitoring detecting is not open, then method 700 proceeds to and ends at end operation 799.

If query 710 determines that a decreasing cell group (CG) resistance rate of change is not detected, then method 700 continues at query 760. At query 760, method 700 determines whether an increasing cell group (CG) resistance rate of change is detected.

If query 760 determines that an increasing cell group (CG) resistance rate of change is detected, then method continues at query 770 as described above. If query 760 determines that an increasing cell group (CG) resistance rate of change is not detected, then method may re-start at start operation 701.

FIG. 8 is a flowchart illustrating a method 800 for determining whether an overcurrent protection element in a RESS 101 has opened, based on cell group capacity. Generally, method 800 calculates capacity, monitors capacity of the individual cell groups, and detects whether one cell group is suddenly behaving like that cell group has a smaller capacity than the other cell groups.

As shown, method 800 may begin at start operation 801. Method 800 includes, at operation 810, measuring the voltage and current of each cell group. Method 800 continues at query 820, with determining whether there is a sufficient charge or discharge. For example, a minimum value of measurable Amp hours is necessary for calculations. When charging a cell group with a certain amount of current for a certain amount of time, the cell group is expected to increase to a certain voltage based on its capacity. If a higher voltage is reached, then capacity has decreased. Query 820 can be performed for a duration of an event, or over a window. For example, for every ten minutes of direct current fast charging (DCFC).

If query 820 determines that there is not a sufficient charge or discharge, the method 800 may re-start at start operation 801.

When query 820 determines that there is a sufficient charge or discharge, the method 800 continues at operation 830. At operation 830, method 800 calculates the capacities of the array of cell groups. For example, operation 830 may use the equation stating that the capacity is equal to the Amp hours transferred divided by the voltage-based state of change (SOC).

Method 800 then continues at query 840. At query 840, method 800 determines whether the capacity of each cell group is substantially equal to its previously calculated capacity. For example, method 800 determines if current capacity C_{N}≈previous capacity C_{N-1} for each cell group. If query 840 determines that the current calculated capacity of each cell group is the same as the previously calculated capacity of each cell group, then method 800 proceeds to operation 850. At operation 850, method 800 concludes that no overcurrent protection element has opened. Method 800 may then proceed to re-start at start operation 801.

If query 840 determines that the current calculated capacity of a cell group is the not that same as the previously calculated capacity of that cell group, then method 800 continues at query 860. At query 860, method 800 determines whether the calculated capacity of the affected cell group is substantially equal to 80% of the previously calculated capacity of the affected cell group. For example, method 800 determines if current capacity C_{N}≈(0.8) previous capacity C_{N-1} for the affected cell group.

If query 860 determines that the calculated capacity of the affected cell group is not substantially equal to 80% of the previously calculated capacity of the affected cell group, then method 800 proceeds to operation 850. At operation 850, method 800 concludes that no overcurrent protection element has opened. Method 800 may then proceed to re-start at start operation 801.

When query 860 determines that the calculated capacity of the affected cell group is substantially equal to 80% of the previously calculated capacity of the affected cell group, then method 800 may continue at operation 870. At operation 870, method 800 concludes that the overcurrent protection element in the affected cell group has opened. Method 800 then continues at operation 880 with controlling operation of the RESS to compensate for the loss of a cell group. For example, operation 880 may include modifying limits and calculations for controlling operation of the RESS.

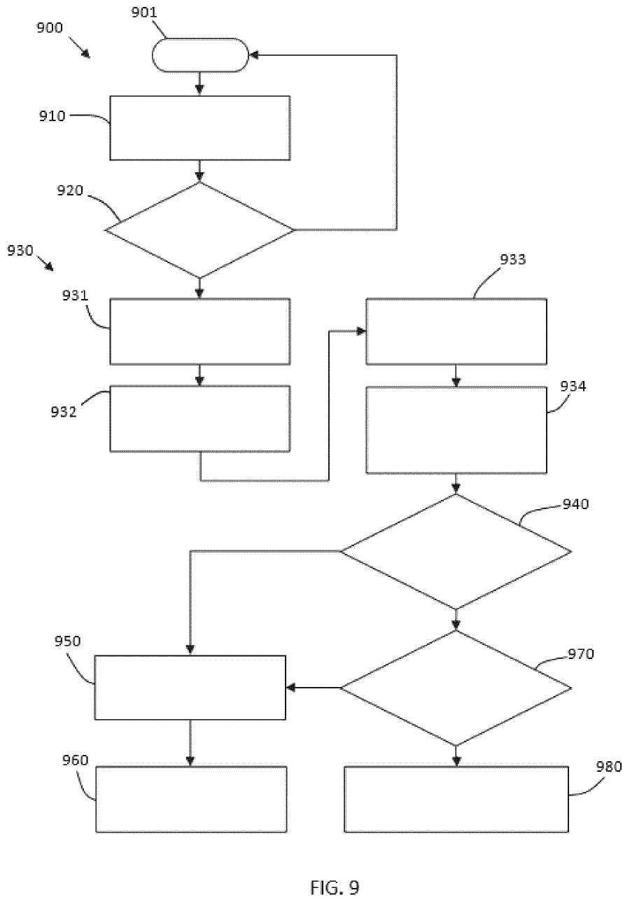

FIG. 9 is a flowchart illustrating a method 900 for determining whether an overcurrent protection element open in a RESS 101 has opened, based on cell group resistance. Generally, method 900 calculates resistance, monitors resistance of the individual cell groups, and detects whether one cell group is suddenly behaving like that cell group has a larger resistance than the other cell groups.

As shown, method 900 may begin at start operation 901. Method 900 includes, at operation 910, measuring the synchronized current and voltage of each cell group. Method 800 continues at query 920, with determining whether there is a sufficient current for performing calculations to determine resistance.

When query 920 determines that there is not sufficient current for performing calculations to determine resistance, method 800 may re-start at start operation 901.

When query 920 determines that there is sufficient current for performing calculations to determine resistance, method 800 may continue at operation 930 with analyzing resistance of each cell group. Specifically, at operation 931, method 900 calculates the present cell group resistance for each cell group. Method 900 continues at operation 932, with filtering the data obtain in operation 931, such as by the use of equation R1=(R0−Ravg)/Ravg.

At operation 933, method 900 continues with calculating subsequent cell group resistances for each cell group. At operation 934, method 900 plots resistance per increment for each cell group and calculates step delta, rate of change (RoC).

Method 900 then continues at query 940. At query 940, method 900 determines whether the step delta is substantially equal to +25%.

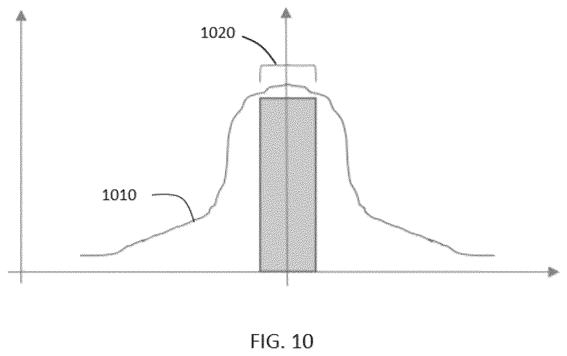

For example, referring to FIG. 10, a graph of resistance per increment is illustrated. As shown, the resistance 1010 exhibits a step change at 1020 of about +25%.

Referring back to FIG. 9, when query 940 determines that the step delta is substantially equal to +25%, method 900 continues at operation 950. At operation 950, method 900 concludes that the overcurrent protection element in the affected cell group has opened. Method 900 then continues at operation 960 with controlling operation of the RESS to compensate for the loss of a cell group. For example, operation 960 may include modifying limits and calculations for controlling operation of the RESS.

When query 940 determines that the step delta is not substantially equal to +25%, method 900 continues at query 970. At query 970, method 900 determines whether the rate of change is outside the range of values for an unfailed part. In certain embodiments, method 900 may determine whether the overcurrent protection element was slow to clear.

If query 970 determines that the rate of change is greater than WPA, then method 900 may continue at operation 950 with concluding that an overcurrent protection element has opened, and proceed to operation 960 to modify RESS operation.

If query 970 determines that the rate of change is not greater than WPA, then method 900 may continue at operation 980 where method 900 concludes that no overcurrent protection element has opened.

The control system 102 of FIG. 1 may perform each of the methods 500, 700, 800, and 900, including combinations of such methods. In certain embodiments, the control system 102 modifies RESS performance by reducing current limits based on the reduced number of cells of the cell group having an opened overcurrent protection element. The control system 102 may use the changed cell group resistance in current and power limits to ensure that voltage limits are not exceeded. Further, the control system 102 may use the reduced capacity of the cell group to adjust the device capability, i.e., vehicle range, and RESS charge time calculations.

Certain embodiments herein derive cell group resistance across RESS high usage conditions in order to monitor for an expected delta caused by a single cell circuit opening.

Certain embodiments herein use current correlation with cell group resistance rate of change to differentiate an internal short circuit related fuse-opening from fuse fatigue.

Certain embodiments herein use cell group resistance rate of change, especially during high loads, to deduce a fuse is partially open but that an arcing or slow-blow effect is preventing a step change for diagnostic.

Certain embodiments herein calculate cell group capacity during predictable conditions to monitor for an expected delta caused by a single cell circuit opening.

Certain embodiments herein use fuse monitor status as a corroborating trigger condition for thermal runaway.

Certain embodiments herein use fuse monitor status and faulted cell group capacity as input to RESS controls for power limits, current limits, and/or voltage limits, in order to protect the RESS from added damage that can lead to safety concerns.

Certain embodiments herein use fuse monitor status as input to RESS controls for range estimates and for charge time estimates in order to provide maximum utility of the RESS.

For example, by using the behavior of the cell group voltage under defined conditions, parameters can be calculated to show the sudden change in behavior that correlates to a cell being disconnected (˜20% capacity drop, ˜25% resistance increase). By calculating the rate of change of cell group voltage under known loads, and monitoring for a change in rate of change that corresponds with 25% increased resistance, it can be determined that a fuse opened. By calculating the individual cell group capacity per discharge or charge event, and monitoring for a change in capacity corresponding with a cell disconnection (e.g. 20%), it can be determined that a fuse opened. By using internal short circuit voltage calculations and using rate of change of cell group resistance, a step indicating a fuse opening due to an internal short circuit can be differentiated.

Certain embodiments detect a cell group that experiences a cell fuse opening via cell group delta capacity. Certain embodiments utilize the impacts of capacity on cell voltage behavior.

Certain embodiments detect that a cell group has experienced a cell fuse opening via cell group delta resistance. Certain embodiments utilize the impacts of resistance on cell voltage behavior.

Certain embodiments differentiate a cell group with a voltage drop (internal short circuit effect) leading up to a fuse opening from a normally-behaving cell group that sees a load dependent voltage change after a fuse opening (ISC vs RESS high current responses).

Certain embodiments use the detection of a cell group as experiencing a cell fuse opening due to a cell internal short circuit as a thermal runaway indication.

Certain embodiments detect a fuse opening in a cell group and use the detection as part of RESS controls to allow continued usage of a RESS with diminished performance.

Certain embodiments may prevent cascading failures of other fuses in the cell group and an ensuing loss of power.

Certain embodiments recognize and mitigate the fact that a cell group that is missing a cell will be prone to over/undervoltage during dynamic uses and result in a combination of cell damage and undesired drivability due to voltage limit violations.

Certain embodiments detect a cell fuse opening under certain thermal runaway conditions, and use the detection as a triggering condition for implementing a thermal runaway protocol for mediating RESS conditions.

Certain embodiments provide for diagnosing RESS performance loss. Certain embodiments provide for correct range estimates during propulsion based on the weakest cell group. Certain embodiments provide for correct calculations of charge times based on the weakest cell group. Certain embodiments provide for isolation of a cell group identified as having a blown fuse to a location in pack (such as for service, propagation monitoring, disconnecting that pack).

It will be appreciated that the systems, vehicles, and methods may vary from those depicted in the Figures and described herein. It will similarly be appreciated that the steps of the methods may differ from that depicted in the Figures, and/or that various steps of the methods may occur concurrently and/or in a different order than that depicted and/or described above in connection therewith.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A method comprising:
operating a device having a rechargeable energy storage system (RESS) including cells arranged in parallel in cell groups, wherein each cell is provided with an overcurrent protection element, by passing a current through the cells based on instructions provided by a processor;
obtaining sensor data via one or more sensors of the device;
determining, via the processor, whether a cell group has a decreasing resistance rate of change;
when the cell group has a decreasing resistance rate of change, determining, via the processor, whether the cell group has a sufficient voltage deviation indicative of an internal short circuit condition;
when the cell group does not have a sufficient voltage deviation indicative of an internal short circuit condition, determining, via the processor, whether the cell group has a voltage rate of change that is unrelated to the current; and
when the cell group has a voltage rate of change that is unrelated to the current, concluding, via the processor, that an internal short circuit exists and modifying operation of the device to prevent damage to the RESS.

2. The method of claim 1, further comprising:
when the cell group has a sufficient voltage deviation indicative of an internal short circuit condition, concluding, via the processor, that an internal short circuit exists and modifying operation of the device to prevent damage to the RESS.

3. The method of claim 2, wherein modifying operation of the device to prevent damage to the RESS comprises cooling the RESS and/or discharging the RESS.

4. The method of claim 2, further comprising:
when the cell group does not have a voltage rate of change that is unrelated to the current, determining, via the processor, whether an overcurrent protection element in the cell group has opened; and
when an overcurrent protection element in the cell group has opened, concluding, via the processor, that the overcurrent protection element opened due to fatigue.

5. The method of claim 4, further comprising:
when the cell group does not have a decreasing resistance rate of change, determining, via the processor, whether the cell group has an increasing resistance rate of change;
when the cell group has an increasing resistance rate of change, determining, via the processor, whether an overcurrent protection element in the cell group has opened; and
when an overcurrent protection element in the cell group has opened, concluding, via the processor, that the overcurrent protection element opened due to fatigue and modifying operation of the device.

6. The method of claim 4, wherein modifying operation of the device comprises:
revising charging and discharging limits of the RESS to avoid damaging the cell group; and
revising RESS output estimates based on a decreased storage capability of the cell group.

7. The method of claim 1, wherein the device is a battery electric vehicle (BEV).

8. The method of claim 1, wherein the device is a hybrid electric vehicle (HEV).

9. A method comprising:
operating a device having a rechargeable energy storage system (RESS) including cells arranged in parallel in cell groups, wherein each cell is provided with an overcurrent protection element, by passing a current through the cells based on instructions provided by a processor;
obtaining sensor data via one or more sensors of the device;
performing, via the processor, an initial diagnosis of the sensor data to ascertain whether an internal short circuit condition exists, wherein the initial diagnosis does not ascertain that an internal short circuit condition exists; and
performing, via the processor, a secondary diagnosis of the sensor data to ascertain whether an internal short circuit condition exists, wherein the secondary diagnosis considers sensor data behavior representative of an opened overcurrent protection element.

10. The method of claim 9, wherein performing the initial diagnosis comprises:
determining whether a voltage of an affected cell group exhibited a voltage decrease with a greater magnitude than a threshold value representative of the internal short circuit condition.

11. The method of claim 10, wherein performing the secondary diagnosis comprises:
determining whether the voltage of the affected cell group exhibited an initial voltage decrease representative of the internal short circuit condition before the voltage of the affected cell exhibited an increasing voltage indicative of the opened overcurrent protection element.

12. The method of claim 10, wherein performing the secondary diagnosis comprises:
determining whether a voltage rate of change of the affected cell group is unrelated to the current.

13. The method of claim 9, further comprising:
when the secondary diagnosis ascertains that an internal short circuit condition does not exist, performing, via the processor, a tertiary diagnosis of the sensor data to ascertain whether an overcurrent protection element has opened.

14. The method of claim 13, wherein performing the tertiary diagnosis comprises:
monitoring a capacity of each cell group and determining that the capacity of the cell group of the affected cell has decreased; and/or
monitoring a resistance of each cell group and determining that the resistance of the cell group of the affected cell has increased.

15. The method of claim 13, further comprising:
when the tertiary diagnosis concludes that an overcurrent protection element has opened, modifying, via the processor, limits and calculations for controlling operation of the device to compensate for the RESS limited by an affected cell group with a diminished capacity.

16. A vehicle comprising:
a rechargeable energy storage system (RESS) including cells arranged in parallel in cell groups, wherein each cell is provided with an overcurrent protection element;
sensors configured to obtain sensor data regarding voltage, resistance, and/or capacity of each cell group;
a processor that is coupled to the sensors and is configured to:
instruct the RESS to pass a current through the cells to drive the vehicle;
obtain the sensor data from the sensors;
perform an initial diagnosis of the sensor data to ascertain whether an internal short circuit condition exists; and
perform a secondary diagnosis of the sensor data to ascertain whether an internal short circuit condition exists, wherein the secondary diagnosis considers sensor data behavior representative of an opened overcurrent protection element.

17. The vehicle of claim 16, wherein the initial diagnosis comprises:
determining whether a voltage of an affected cell group exhibited a voltage decrease with a greater magnitude than a threshold value representative of the internal short circuit condition.

18. The vehicle of claim 17, wherein the secondary diagnosis comprises:
determining whether the voltage of the affected cell group exhibited an initial voltage decrease representative of the internal short circuit condition before the voltage of the affected cell exhibited an increasing voltage indicative of the opened overcurrent protection element.

19. The vehicle of claim 18, wherein the secondary diagnosis comprises:
determining whether the voltage rate of change of the affected cell group is unrelated to the current.

20. The vehicle of claim 16, wherein:
the processor is configured to perform a tertiary diagnosis of the sensor data to ascertain whether an overcurrent protection element has opened;
the tertiary diagnosis comprises:
monitoring the capacity of each cell group and determining that the capacity of the cell group of the affected cell has decreased; and/or
monitoring the resistance of each cell group and determining that the resistance of the cell group of the affected cell has increased; and
the processor is configured to modify limits and calculations for controlling operation of the vehicle to compensate for the RESS limited by the affected cell group with a diminished capacity when the tertiary diagnosis concludes that an overcurrent protection element has opened.
